(19) United States
(12) Patent Application Publication
(10) Pub. No.: US 2025/0131171 A1
(43) Pub. Date: Apr. 24, 2025

(54) IDENTIFYING EXCESS ANTENNAS WITHIN INTEGRATED CIRCUIT DESIGNS

(71) Applicant: International Business Machines Corporation, Armonk, NY (US)

(72) Inventors: Amanda Christine VENTON, Austin, TX (US); Eric Chien LAI, Cedar Park, TX (US); David WOLPERT, Poughkeepsie, NY (US); Michael Alexander BOWEN, Poughkeepsie, NY (US); Miles C. PEDRONE, Highland, NY (US)

(21) Appl. No.: 18/491,575

(22) Filed: Oct. 20, 2023

(51) Int. Cl. G06F 30/323; G06F 30/31; G06F 30/392

(52) U.S. Cl. CPC G06F 30/323; G06F 30/31; G06F 30/392

(57) ABSTRACT

Embodiments herein describe techniques for identifying excess antennas (or antenna diodes) in a IC design using computer software tools. An IC design can be changed for any number of reasons, which can change the number of antennas that are required to sufficiently protect the IC from damage during the fabrication process. Currently, a chip designer would use a ratio to determine whether a portion of the IC (e.g., a macro) has too many or too few antennas. The embodiments herein describe techniques where computer software tools identify excess antennas for the designer. The designer can then decide whether to remove these antennas. In another embodiment, the computer software tools may automatically remove some or all of the identified excess antennas, without input from the chip designer.

### BACKGROUND

The present invention generally relates to integrated circuit design, and more specifically, to identifying excess antenna diodes in an integrated circuit design.

The development of an integrated circuit (i.e., IC or chip) involves several stages from design through fabrication. The IC may be subdivided into hierarchical levels to simplify design and testing tasks at different stages. Generally, a cell or macro may be regarded as a sub-section or a portion of the IC. For example, each macro may include a number of cells. Once the design is finalized, tests may be completed to ensure that design rules established by a foundry are met prior to fabrication.

During the design of macros, antenna diodes are often manually added to the layout of the macro to provide a contact from a metal layer to a diffusion layer of a device for manufacturing purposes. This contact provides a path for charge generated in long metal lines or in large via areas during manufacturing to be dissipated without damaging a transistor gate (e.g., a gate oxide) or other circuit implemented on a semiconductor substrate. No prior art techniques currently available provide a method for identifying excess antenna diodes.

### SUMMARY

According to one embodiment of the present invention, a method includes receiving a change to a netlist, wherein the netlist defines a design of an integrated circuit (IC), identifying, using one or more computer processors, an excess antenna diode in the design of the IC, wherein the excess antenna diode is configured to remove charge buildup in a metal layer when the IC is being fabricated, and removing or shrinking the excess antenna diode in a layout of the IC using the one or more computer processors.

According to one embodiment of the present invention, a system includes one or more processors and memory storing an application which, when executed by the one or more processors, performs an operation. The operation includes receiving a change to a netlist, wherein the netlist defines a design of an integrated circuit (IC), identifying, using one or more computer processors, an excess antenna diode in the design of the IC, wherein the excess antenna diode is configured to remove charge buildup in a metal layer when the IC is being fabricated, and removing or shrinking the excess antenna diode in a layout of the IC.

According to one embodiment of the present invention, a computer program product for updating a layout of an IC, the computer program product including a computer-readable storage medium having computer-readable program code embodied therewith, the computer-readable program code executable by one or more computer processors to perform an operation. The operation includes receiving a change to a netlist, wherein the netlist defines a design of an integrated circuit (IC), identifying, using one or more computer processors, an excess antenna diode in the design of the IC, wherein the excess antenna diode is configured to remove charge buildup in a metal layer when the IC is being fabricated, and removing or shrinking the excess antenna diode in a layout of the IC.

### BRIEF DESCRIPTION OF THE DRAWINGS

FIG. 1 illustrates a computing environment, according to one embodiment.

FIG. 2 illustrates a workflow for designing a layout and fabricating an integrated circuit, according to one embodiment.

FIG. 3 is a flowchart for identifying excess antennas in a design of an integrated circuit, according to one embodiment.

FIG. 4 is a flowchart for identifying excess antennas in a design of an integrated circuit, according to one embodiment.

FIG. 5 is a flowchart for fabricating an integrated circuit, according to one embodiment.

### DETAILED DESCRIPTION

Embodiments herein describe techniques for identifying excess antenna diodes (also referred to herein as simply “antennas”) in an IC design using computer software tools. An IC design can be changed for any number of reasons, which can change the number of antennas that are required to sufficiently protect the IC from damage during the fabrication process. Currently, a chip designer would use a ratio to determine whether a portion of the IC (e.g., a macro) has too many or too few antennas. The embodiments herein describe techniques where computer software tools identify excess antennas for the designer. The designer can then decide whether to remove these antennas. In another embodiment, the computer software tools may automatically remove some or all of the identified excess antennas, without input from the chip designer.

The descriptions of the various embodiments of the present invention will be presented for purposes of illustration, but are not intended to be exhaustive or limited to the embodiments disclosed. Many modifications and variations will be apparent to those of ordinary skill in the art without departing from the scope and spirit of the described embodiments. The terminology used herein is chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as excess antenna detector 200 (e.g., software code). As discussed in more detail below, the excess antenna detector 200 can be used to identify (and in some cases automatically remove) excess antennas in a design of an integrated circuit (e.g., a layout). In addition to excess antenna detector 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and excess antenna detector 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

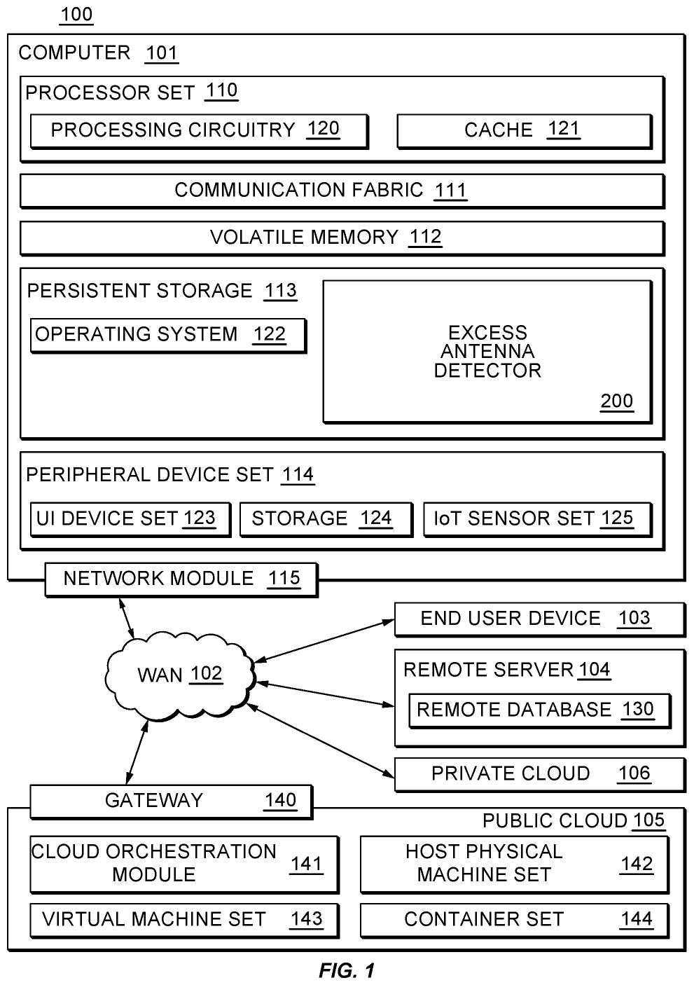

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in excess antenna detector 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

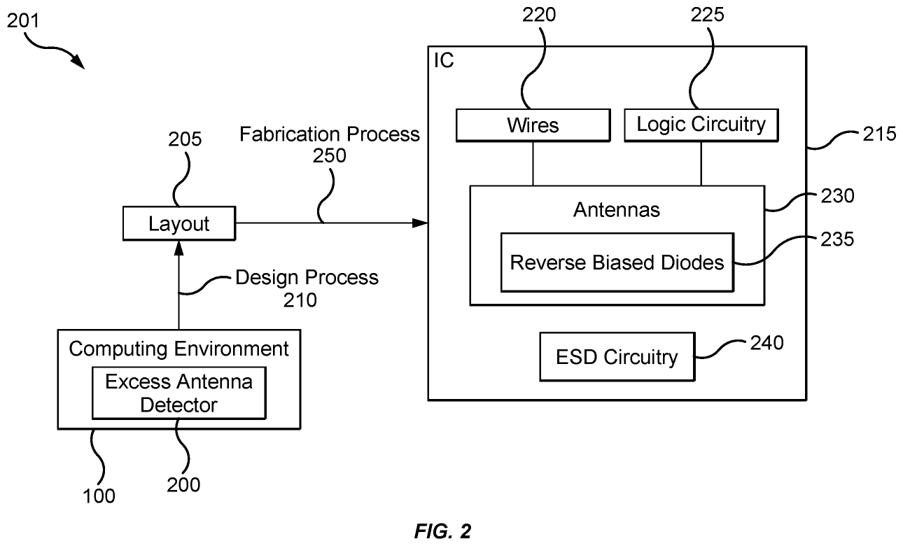

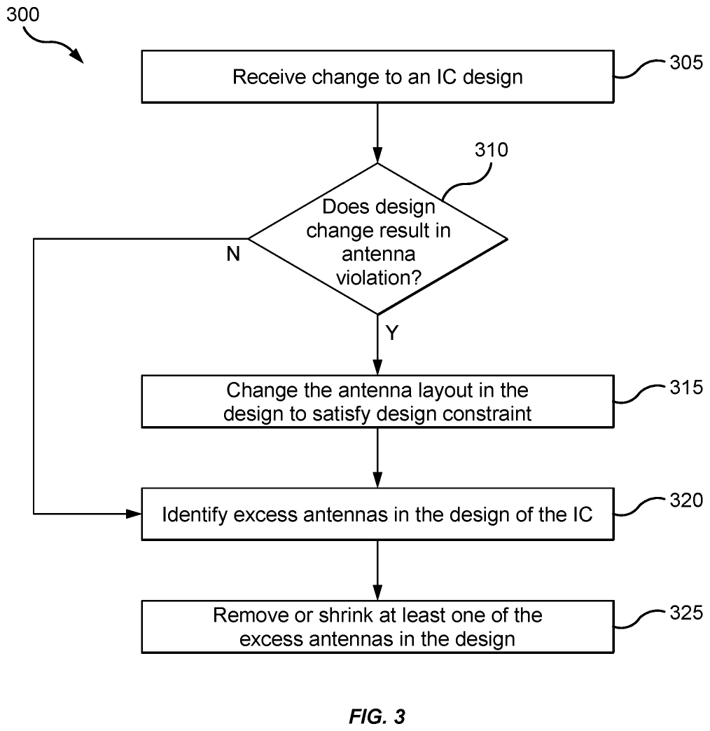

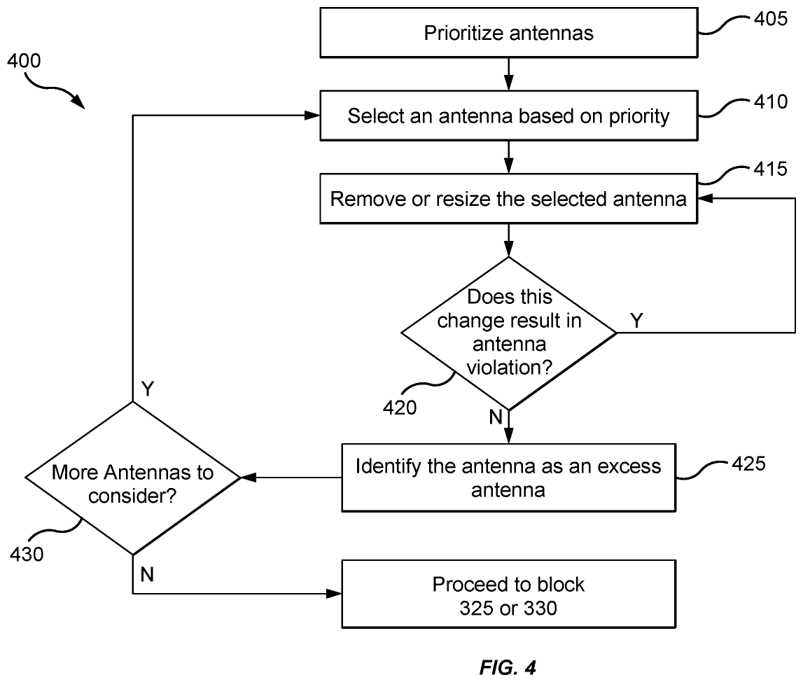

FIG. 2 illustrates a workflow 201 for designing a layout 205 and fabricating an IC 215, according to one embodiment. In this example, the computing environment 100 described above in FIG. 1 can be used to generate a layout 205 which defines a design of the IC 215 as part of a design process 210. As part of the design process 210 (which will be discussed in more detail in FIGS. 3 and 4), the excess antenna detector 200 can identify excess antennas 230 (or antenna diodes) in the layout 205.

During a fabrication process 250, the layout 205 is used to generate masks that can be used to fabricate the IC 215. For example, the IC 215 may be part of a semiconductor wafer that is processed to generate multiple instances of the IC 215.

In this example, the IC 215 includes wires 220 (e.g., traces, clock meshes, etc.) and logic circuitry 225 (e.g., logic gates such AND, NAND, XOR, NXOR, etc.). As discussed above, charge may build up on metal layers in the IC 215 during fabrication due to, e.g., plasma etching and other procedures. These procedures may occur in the front-end of line (FEOL) or middle-end of line (MEOL) of the fabrication process 250. A large build-up of charge during plasma etching and other procedures can induce antenna-like effects on a given wire (“Antenna Effect”). These charge buildups can occur in the metal layers of the wires 220 and the logic circuitry 225. If this charge buildup discharges through an active gate/functional circuit (e.g., a gate oxide in the logic circuitry 225), it can cause it to fail in a variety of ways (changing Vt, I-V characteristic deterioration, or lowered life expectancy).

To dissipate charge buildup during fabrication, the IC 215 includes the antennas 230 which are connected to the metal layers in the wires 220 and the logic circuitry 225. In one embodiment, the antennas 230 are implemented using reverse biased diodes 235, but any type of suitable circuit can be used which dissipates the charge build up. In one embodiment, the reverse biased diodes 235 are on the same connected wire to provide an alternate discharge-path for the built-up current and prevent gate damage. For example, as defined in the layout 205, the reverse biased diodes 235 may include a gate and a source (or a drain) that are coupled to the same net in the layout 205. As such, the reverse biased diodes 235 are leaky circuits that permit charge to leak through, but do not have a logic function in the circuit.

In this embodiment, the IC 215 also includes electrostatic discharge (ESD) circuitry 240 or some other charge dissipation circuitry. However, the ESD circuitry 240 may be formed at the end-of line (EOL) of the fabrication process 250, which means it is not available to discharge built up charge during the FEOL or MEOL of the fabrication process 250. The antennas 230 can fulfill this role during the FEOL or MEOL to prevent harm to the gate oxides. During operation (or when the IC 215 is finished being fabricated), the ESD circuitry 240 may prevent charge build up from environmental conditions from harming the IC 215. Thus, the antennas 230 and the ESD circuitry 240 may both remove excess charge, but during different times and can be very different types of circuits.

FIG. 3 is a flowchart of a method 300 for identifying excess antennas in a design of an integrated circuit, according to one embodiment. At block 305, the computing environment (e.g., the computing environment 100 in FIG. 1) receives a design change to an IC. As an example, the design change may be a change to a layout (e.g., the layout 205 in FIG. 2). Using a clock mesh as an example, it may be important that a clock signal reaches a destination at a particular time (not too early and not too late). The width of wires (e.g., the wires 220 in FIG. 2) can affect the propagation time of the clock signal. Thus, at a first time in the design process, a clock designer may assign a wide trace to the clock signal, but at a second time may determine this means the clock signal arrives too early at its destination, and instead changes the design of the IC (e.g., the layout) to have a narrower wire. In another example, there may be a logical error in the logical circuitry (e.g., the logical circuitry 225 in FIG. 2) which means the chip designer may replace or change the logical circuitry at a particular macro of the IC by again updating the layout. However, these are just several non-limiting examples of when the design of an IC may change.

At block 310, the computing environment determines whether the design change results in an antenna violation. For example, the computing environment can include software tools for determining whether the change made at block 305 means one or more design rules associated with the antennas have been violated. In one embodiment, the software tools may use one or more metal-antenna ratios to determine whether a design rule has been violated. One example of a metal-antenna design rule checking (DRC) rule is a maximum ratio of each metal level connected to a gate area relative to a combination of the gate area and a receive area that is electrically connected to the gate. Other metal-antenna DRC rules can consider other ratios such as considering the thick gate oxide (EG) when determining the ratio. These gate oxides are the gates that are being protected when charge builds up during fabrication. The DRC rules verify whether a specific design meets the constraints imposed by the process technology to be used for its manufacturing. DRC checking is an important part of the physical design flow and ensures the design meets manufacturing requirements and will not result in a chip failure.

The software tools can calculate the metal-antenna ratio(s) for the entire IC or a portion of the IC (e.g., a macro) and determine whether the ratios violate thresholds defined in the metal-antenna DRC rules (e.g., the ratio must be less than or equal to a threshold).

If the change violates a DRC rule, this may mean that there are not enough antennas in the design, and as such, the method 300 proceeds to block 315 the software tools change the antenna layout in the design to satisfy design constraints. For example, the software tools may add additional antennas to the layout in order to improve the metal-antenna ratios so they satisfy the DRC rules. Instead of the software tools adding the antennas automatically, the chip designer may be made aware that the antenna violation occurred and add more antennas.

After making these changes to the antenna layout in the design (or if the design change does not result in an antenna violation at block 310), the method 300 proceeds to block 320 where the antenna excess detector identifies excess antennas in the design of the IC. For example, the design change received at block 305 may have reduced the width of a wire, or removed some circuitry from the IC, which may mean fewer antennas (or smaller antennas) are needed to satisfy the design rules.

Even if the design change meant more antennas were added to the design at block 315, the tools or the chip designer may have added more antennas than were needed in order to overcome the antenna violation and satisfy the design rules. For example, if a clock mesh wire was widened, the chip designer may have added more antennas (or attached a much large antenna) than was needed given the increase in the metal. Thus, the antenna excess detector can identify excess antennas in the design regardless if more metal, or less metal was added to the design.

In one embodiment, there may be different types and sizes of antennas (or different types and sizes of reverse biased diodes) that can be added to the IC design. For example, some antennas may be compatible with FEOL processes, while other may be compatible only with MEOL processes. Also, some antennas may be larger (e.g., 2×, 4×, 10×, larger than a minimum size reverse biased diode) than other antennas of the same type.

Different techniques for identify the excess antennas will be discussed in FIG. 4 below. However, in general, an “excess antenna” is an antenna that can be removed from the IC design (e.g., the layout), or changed to a smaller antenna, and still satisfy the antenna design rules (e.g., the metal-to-antenna ratios).

After identifying the excess antennas, the method 300 proceeds to block 325 where the software tools remove or shrink at least one of the identified excess antennas in the design. In one embodiment, the excess antennas identified at block 320 are displayed to the chip designer using an I/O interface (e.g., a monitor and a user interface (UI). A chip designer can use the knowledge of the identified excess antennas to remove or shrink these antennas. For example, the chip designer may decide to simply remove the excess antennas from the layout. Or the chip designer may know that in a later design step (e.g., if the design process is part of a hierarchy), more antennas may be needed, and as a result may not remove all (or may not remove any) of the excess antennas that were identified by the antenna excess detector.

In another embodiment, instead of removing the excess antennas, the chip designer may use smaller antennas, which also can save space in the design. For example, for clock meshes, a clock designer may be more worried about the capacitance caused by connecting multiple antennas to the clock mesh wires and choose to remove the excess antennas rather than shrinking them. In other situations, it may be more important to a chip designer to replace larger excess antennas with smaller antennas, rather than completely removing them since this may save more space in a single area of the chip (relative to removing a bunch of smaller excess antennas spread out over the chip). Thus, at block 325, the chip designer may be tasked with taking an action (or deciding no action should be taken) in response to the antenna excess detector identifying excess antennas. In either case, the software tools can use the chip designer's instructions as input in order to remove or shrink at least one excess antenna in the layout.

In another embodiment, the software tools automatically remove or change the antenna layout to remove excess antennas, without input from the chip designer. The software tools may use programmatic rules or machine learning to remove or reduce the size of the excess antennas. However, the chip designer may set parameters that the software tools uses when removing excess antennas. For example, the chip designer may designate certain nets (or certain macros) as “do not change” areas of the layout so that any identified excess antennas that connect to those nets or macros are not removed or changed. Or the chip designer may specific nets or macros where the software tool should assign higher priority on removing excess antennas. The software tools may first try to remove excess antenna from these areas or nets before attempting to remove excess antennas from other areas or nets.

FIG. 4 is a flowchart of a method 400 for identifying excess antennas in a design of an integrated circuit, according to one embodiment. The method 400 is one embodiment of performing block 320 in FIG. 3 where the excess antenna detector identifies excess antennas in the design of the IC (e.g., a layout).

At block 405, the excess antenna detector prioritizes the antennas in the antenna layout. For example, the excess antenna detector may sort the antennas by largest to smallest antennas and then evaluate the ratio. In another example, the excess antenna detector may prioritize the antennas based on a density of the antennas, where antennas in a large density of other antennas are given a higher priority than antennas in a smaller density. In yet another example, the excess antenna detector may prioritize antennas based on how many are connected to the same net. For example, multiple antennas that are connected to the same net (e.g., the same wire) in the layout may be given a higher priority than an antenna that is the only one connected to a net. However, these are just a few examples of techniques for prioritizing the antennas. The technique used to prioritize the antennas may depend on the goals of the chip designer—e.g., whether to minimize the total number of antennas coupled to wires versus trying to free up large blocks of space in the design by removing larger excess antennas.

At block 410, the excess antenna detector selects an antenna based on priority. For example, the excess antenna detector may first select the highest priority antenna to consider.

At block 415, the excess antenna detector removes or resizes the selected antenna. For example, the excess antenna detector may first remove the antenna from the design and then proceed to block 420 to determine whether doing so caused an antenna violation (e.g., violates one of the DRC rules discussed at block 310 of method 300). If so, the method 400 can return to block 415 where the excess antenna detector next shrinks the antenna to the smallest antenna size (e.g., from 4× to 1×). The method 400 can then return to 420 to again determine if this change results in an antenna violation. If so, the method 400 can again to return to block 415 where instead of shrinking the antenna to the smallest size, the excess antenna detector shrinks it to the next smallest size (e.g., from 1× to 2×) and again checks whether this satisfies the metal-to-antenna ratios at block 420. This can continue until the excess antenna detector determines the smallest size the antenna can be shrunk to and still satisfy the DRC rules.

Assuming it is possible to shrink (or remove completely) the selected antenna, the method 400 proceeds to block 425 where the antenna is identified as an excess antenna. After identifying an excess antenna (or if it is not possible to remove or shrink the currently selected antenna without causing an antenna violation), the method 400 proceeds to block 430 where the excess antenna detector determines whether there are more antennas to consider. If so, the method 400 returns to block 410 to select another antenna based on the priority (e.g., the antenna with the next highest priority) and then repeats the method 400 to determine whether that antenna can be removed or shrunk without causing an antenna violation. In this manner, the method 400 can iterate through the current antennas in the layout and identify which antennas are, and which ones are not, excess antennas. The method 400 can then return to block 325 in FIG. 3.

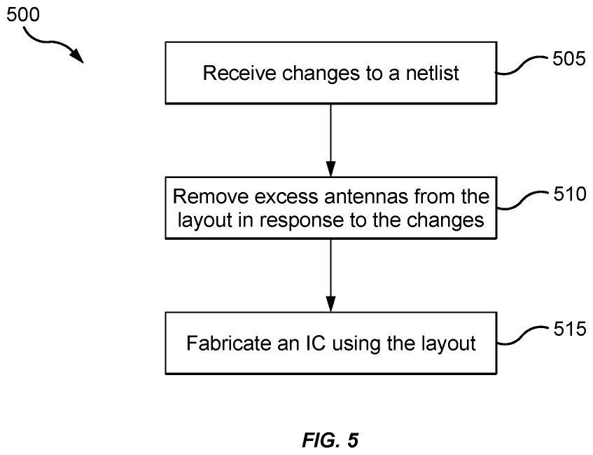

FIG. 5 is a flowchart of a method 500 for fabricating an integrated circuit, according to one embodiment. At block 505, the computing environment receives changes to a netlist. The changes may be the same as the ones disclosed at block 305 in method 300. As discussed above, these changes may result in there being excess antennas in the netlist.

The netlist is one aspect of a layout representing the different parts of an IC that need to be connected. The layout can include the full set of design information that encompasses: the netlist, shapes on the metal layers and their locations that actually implement the net connections, other sub-circuits and designs, among many other things.

At block 510, one or more excess antennas are removed from the layout in response to the changes. For example, the method 500 may rely on the techniques discussed in FIGS. 3 and 4 to identify the excess antennas. These excess antennas can then be removed by a chip designer, automatically by a software tool, or some combination of both.

At block 515, an IC is fabricated using the layout after all design changes have been made to the layout. Each time a design change is made, the chip designer or software tool may decide whether to remove excess antennas. Further, while outside the scope of this patent application, the chip designer or software tool may also decide to add antennas in response to a design change. As such, after some design changes, antennas may only be added to the design, while after other design changes antennas may only be removed or shrunk, and after still other design changes, antennas may both be added and removed/shrunk.

Once the layout is finalized, it can be used to generate masks that can be in turn used to fabricate the IC in a semiconductor wafer.

While the foregoing is directed to embodiments of the present invention, other and further embodiments of the invention may be devised without departing from the basic scope thereof, and the scope thereof is determined by the claims that follow.

What is claimed is:

1. A method comprising:
receiving a change to a netlist, wherein the netlist defines a design of an integrated circuit (IC);
identifying, using one or more computer processors, an excess antenna diode in the design of the IC, wherein the excess antenna diode is configured to remove charge buildup in a metal layer when the IC is being fabricated; and
removing or shrinking the excess antenna diode in a layout of the IC using the one or more computer processors.

2. The method of claim 1, wherein the excess antenna diode comprises a reverse biased diode.

3. The method of claim 2, wherein a gate and a source or drain in the reverse biased diode are coupled to a same net in the netlist.

4. The method of claim 1, wherein identifying the excess antenna diode comprises:
prioritizing a plurality of antenna diodes in the layout; and
iterating through the plurality of antenna diodes based on the prioritization to determine which of the plurality of antenna diodes can be removed or shrunk without resulting in an antenna violation.

5. The method of claim 4, wherein the antenna violation is based on a metal-antenna ratio in the layout of the IC.

6. The method of claim 1, wherein the excess antenna diode is configured to prevent harm to a gate oxide in the IC during the fabrication process.

7. The method of claim 1, further comprising:
transmitting for displaying the identified excess antenna diode; and
receiving instructions to remove or shrink the excess antenna diode via a user interface (UI).

8. The method of claim 1, wherein removing or shrinking the excess antenna diode is performed automatically by a software tool, without user intervention.

9. The method of claim 8, further comprising:
receiving parameters for the software tool to use when removing or shrinking the excess antenna diode, the parameters comprises at least one of: designating an area of the layout of the IC where excess antenna diodes cannot be removed, or designating an area of the layout of the IC that has a higher priority when removing excess antenna diodes.

10. A system, comprising:
one or more processors; and
memory storing an application which, when executed by the one or more processors, performs an operation, the operation comprising:
receiving a change to a netlist, wherein the netlist defines a design of an integrated circuit (IC);
identifying an excess antenna diode in a layout of the IC, wherein the excess antenna diode is configured to remove charge buildup in a metal layer when the IC is being fabricated; and
removing or shrinking the excess antenna diode in the layout.

11. The system of claim 10, wherein the excess antenna diode comprises a reverse biased diode, wherein a gate and a source or drain in the reverse biased diode are coupled to a same net in the netlist.

12. The system of claim 10, wherein identifying the excess antenna diode comprises:
prioritizing a plurality of antenna diodes in the layout; and
iterating through the plurality of antenna diodes based on the prioritization to determine which of the plurality of antenna diodes can be removed or shrunk without resulting in an antenna violation.

13. The system of claim 12, wherein the antenna violation is based on a metal-antenna ratio in the layout of the IC.

14. The system of claim 11, wherein the excess antenna diode is configured to prevent harm to a gate oxide in the IC during the fabrication process.

15. A computer program product for updating a layout of an IC, the computer program product comprising:
a computer-readable storage medium having computer-readable program code embodied therewith, the computer-readable program code executable by one or more computer processors to perform an operation, the operation comprising:
receiving a change to a netlist, wherein the netlist defines a design of the IC;
identifying, using one or more computer processors, an excess antenna diode in the layout of the IC, wherein the excess antenna diode is configured to remove charge buildup in a metal layer when the IC is being fabricated; and
removing or shrinking the excess antenna diode in the layout.

16. The computer program product of claim 15, wherein the excess antenna diode comprises a reverse biased diode.

17. The computer program product of claim 16, wherein a gate and a source or drain in the reverse biased diode are coupled to a same net in the netlist.

18. The computer program product of claim 15, wherein identifying the excess antenna diode comprises:
prioritizing a plurality of antenna diodes in the layout; and
iterating through the plurality of antenna diodes based on the prioritization to determine which of the plurality of antenna diodes can be removed or shrunk without resulting in an antenna violation.

19. The computer program product of claim 18, wherein the antenna violation is based on a metal-antenna ratio in the design of the IC.

20. The computer program product of claim 15, wherein the excess antenna diode is configured to prevent harm to a gate oxide in the IC during the fabrication process.
